(19) United States
(12) Patent Application Publication
(10) Pub. No.: US 2026/0323843 A1
(43) Pub. Date: Oct. 15, 2026

(54) SYSTEM AND METHOD FOR RAPID FORMATION OF CONDUCTIVE VIAS IN PRINTED CIRCUIT BOARDS

(71) Applicant: UFab Corporation, Chicago, IL (US)

(72) Inventor: Tyler Richards, Chicago, IL (US)

(21) Appl. No.: 19/643,187

(22) Filed: Apr. 9, 2026

Related U.S. Application Data
(60) Provisional application No. 63/787,531, filed on Apr. 11, 2025.

(51) Int. Cl. H05K 3/42; C25D 5/02

(52) U.S. Cl. CPC H05K 3/422; C25D 5/02; H05K 2203/107

(57) ABSTRACT

A system and method for forming a conductive via in a printed circuit board substrate are provided. The method includes obtaining a printed circuit board substrate that includes a dielectric material between a first conductive layer and a second conductive layer, directing a pulsed laser through the printed circuit board substrate to form a through hole, and forming along a side wall of the through hole a partially conductive region that includes carbonized dielectric material and metal dust. At least one of the first conductive layer or the second conductive layer is electrically coupled to a cathode, the printed circuit board substrate is immersed in an electroplating bath, and conductive material is electroplated onto the side wall of the through hole through electrical conduction provided by the partially conductive region to form the conductive via.

### CROSS-REFERENCE TO RELATED APPLICATIONS

This application claims priority to U.S. Provisional Application No. 63/787,531 (filed 11-Apr-2025), the entire disclosure of which is incorporated herein by reference.

### TECHNICAL FIELD

The subject matter described herein relates to the field of electronics, specifically to methods and systems for forming conductive vias in printed circuit boards.

### BACKGROUND

The subject matter described herein relates to the field of printed circuit board fabrication, where the formation of conductive vias using through holes plays a significant role in establishing electrical interconnections among electronic components. Manufacturers in this technical area have traditionally relied on drilling techniques—either mechanical or via laser sources—to create openings that can subsequently be metallized to create conductive vias. The increasing complexity and miniaturization of electronic circuitry have driven the need for precise control over these processes. As electronics continue to evolve toward higher density and performance, ensuring the reliability of interconnects has become increasingly important. However, existing methods frequently demand several additional processing steps post-drilling, highlighting a need for more efficient approaches within this field.

In many manufacturing settings, the goal is to achieve rapid, cost-effective, and high-quality production of printed circuit boards that feature densely packed interconnect pathways. Industry participants seek solutions that not only facilitate the formation of conductive vias with tight tolerances but also integrate smoothly into existing assembly lines. The drive for improved productivity is accentuated by the trends in high-speed electronics, where even minor inefficiencies can impact overall system performance. Achieving robust electrical performance while reducing equipment downtime and process complexity remains an important applicative goal, addressing the demands of both high-volume production and prototyping activities in modern electronics manufacturing.

Current processes that establish electrical connectivity on printed circuit boards often incorporate multiple sequential steps, including drilling, surface treatment, and metallization. Such arrangements typically require extensive cleaning and chemical processes to prepare the drilled openings for effective conductive deposition. These additional procedures contribute to longer cycle times and elevated manufacturing costs, while also necessitating careful handling of hazardous substances. Moreover, the limited integration and coordination among these steps can lead to variable performance, especially when precise conformality of the metallized layer is desired. Hence, the inefficiencies of these multi-step approaches underscore the broader challenges faced by the electronics manufacturing industry in achieving streamlined production.

A more specific challenge arises when forming extremely small or high aspect-ratio vias, where conventional cleaning and chemical activation methods may not yield a uniformly conductive layer. The intricate balance between adequately preparing the via surfaces and avoiding excessive treatment can restrict the efficiency with which conductive layers are deposited, leading to inconsistent electrical characteristics. This situation is compounded in manufacturing environments that operate under tight throughput constraints, where time-intensive procedures adversely affect productivity. Additionally, the reliance on potentially hazardous chemicals raises operational and environmental concerns that further complicate integration into modern high-speed production lines. These specific issues collectively highlight the need for alternative process methodologies that minimize process steps, reduce chemical usage, and deliver consistent, reliable conductive pathways.

For example, in some known mechanical drilling processes, a CNC drill uses drill bits to cut through a PCB panel to form drill holes or laser drilling uses a focused CO₂ or UV laser that ablates the dielectric layer to create holes. After the holes are drilled, the board undergoes cleaning and desmear. In mechanically drilled holes, burrs on the hole edges are removed during deburring, and resin smear caused by drilling heat is eliminated chemically or via plasma. This thorough cleaning often includes a micro-etch chemical to roughen the exposed copper surfaces, promoting good adhesion during the subsequent metallization steps. Between chemical and mechanical process steps, boards are often further cleaned in water, acid, or activator solutions.

Electroless copper deposition is then used to provide a seed layer that makes the walls of the holes conductive. The board is immersed in a bath containing copper ions and a reducing agent that chemically deposits a thin copper coating on both the inner hole walls and any exposed copper surfaces. Once this conductive base is in place, the board moves to an electrolytic plating tank, where the board is connected to a power supply and paired with a copper anode. As current flows, copper ions from the solution plate onto the now-conductive surfaces, gradually thickening the via walls to meet design requirements.

This process is time consuming, requires a large number of noxious and expensive chemicals, and requires large amounts of space. In a PCB production environment that values high speed production, low costs, and ease of use, removing as many of these steps as possible is desired.

### BRIEF SUMMARY

In one example, a method for forming a conductive via in a printed circuit board substrate may include obtaining a printed circuit board substrate comprising a dielectric material disposed or located between a first conductive layer and a second conductive layer. The method may include directing a pulsed laser through the printed circuit board substrate to form a through hole extending between the first conductive layer and the second conductive layer. The pulsed laser may form, along a side wall of the through hole, a partially conductive region comprising carbonized dielectric material and metal dust deposited from at least one of the first conductive layer or the second conductive layer. The method may include electrically coupling at least one of the first conductive layer or the second conductive layer to a cathode. The method may include immersing the printed circuit board substrate in an electroplating bath. The method may include electroplating conductive material onto the side wall of the through hole through electrical conduction provided by the partially conductive region to form the conductive via.

The dielectric material may comprise FR-4. The partially conductive region may extend continuously through a thickness of the printed circuit board substrate along the side wall of the through hole. The partially conductive region may provide an electrically connected path between opposite surfaces of the printed circuit board substrate before completion of bulk electroplating. The pulsed laser may have a wavelength of 355 nm. The pulsed laser may have a pulse width of 14 nanoseconds. Directing the pulsed laser may include moving a laser beam along a bidirectional cross-hatch pattern.

The method also may include performing a cleanup pass on the side wall of the through hole after directing the pulsed laser and before immersing the printed circuit board substrate in the electroplating bath. Performing the cleanup pass may include moving the pulsed laser along a length of the through hole at a speed of at least 500 millimeters per second to remove resin or glass melt from the side wall of the through hole. The method also may include immersing the printed circuit board substrate in an ion sequestration bath after electroplating the conductive via. The ion sequestration bath may comprise a sodium carbonate solution that can convert soluble copper ions remaining on the printed circuit board substrate into an insoluble copper compound.

In another example, a method for forming a conductive via in a printed circuit board substrate may include forming a circuit pattern in a first conductive layer and a second conductive layer disposed or located on opposite surfaces of a printed circuit board substrate. The method may include disposing or depositing a first non-conductive layer on the first conductive layer and disposing or depositing a second non-conductive layer on the second conductive layer. The method may include disposing or depositing a first outer conductive layer on the first non-conductive layer and disposing or depositing a second outer conductive layer on the second non-conductive layer. The method may include directing a laser through the first outer conductive layer, the first non-conductive layer, the printed circuit board substrate, the second non-conductive layer, and the second outer conductive layer to form a through hole having a side wall including a partially conductive region. The method may include electrically coupling at least one of the first outer conductive layer or the second outer conductive layer to a cathode. The method may include immersing the printed circuit board substrate in a plating bath. The method may include electroplating conductive material onto the side wall of the through hole through the partially conductive region while the first non-conductive layer and the second non-conductive layer inhibit electroplating on the circuit pattern to form the conductive via.

The first outer conductive layer and the second outer conductive layer may each comprise copper tape. At least one of the first non-conductive layer or the second non-conductive layer may comprise Kapton tape. The Kapton tape may have a thickness of 1 mil. At least one of the first outer conductive layer or the second outer conductive layer may have a thickness of 1 mil. The method also may include removing the first outer conductive layer and the second outer conductive layer after electroplating the conductive via.

In another example, a method for selectively electroplating a through hole in a printed circuit board substrate may include providing a printed circuit board substrate comprising a dielectric material disposed or located between a first conductive layer and a second conductive layer. The method may include disposing or depositing a first non-conductive adhesive sheet on the first conductive layer and disposing or depositing a second non-conductive adhesive sheet on the second conductive layer. The method may include directing a laser through the first non-conductive adhesive sheet, the printed circuit board substrate, and the second non-conductive adhesive sheet to form a through hole having a side wall including a partially conductive region. The method may include electrically coupling at least one of the first conductive layer or the second conductive layer to a cathode. The method may include immersing the printed circuit board substrate in an electroplating bath while the first non-conductive adhesive sheet and the second non-conductive adhesive sheet cover surface regions adjacent the through hole. The method may include electroplating conductive material onto the side wall of the through hole through the partially conductive region to form the conductive via.

The method also may include removing the first non-conductive adhesive sheet and the second non-conductive adhesive sheet after an initial portion of the electroplating and returning the printed circuit board substrate to the electroplating bath. The first non-conductive adhesive sheet and the second non-conductive adhesive sheet may reduce an area available for electroplating to increase current density at the through hole during an initial portion of the electroplating. The first non-conductive adhesive sheet and the second non-conductive adhesive sheet may expose the through hole to the electroplating bath while covering surrounding surface regions of the printed circuit board substrate during an initial portion of the electroplating. Continued electroplating after removing the first non-conductive adhesive sheet and the second non-conductive adhesive sheet may deposit the conductive material onto at least one of the first conductive layer or the second conductive layer adjacent the through hole.

### BRIEF DESCRIPTION OF DRAWINGS

The subject matter may be understood from reading the following description of non-limiting embodiments, with reference to the attached drawings, wherein below:

FIG. 1 is a system diagram illustrating the conductive via forming system for printed circuit boards.

FIG. 2 is a schematic diagram illustrating the laser drilling process for forming vias in a PCB substrate.

FIG. 3 illustrates a bidirectional cross hatch pattern used in laser drilling for forming vias.

FIG. 4 is a system diagram illustrating the drilling mechanism for forming through holes in a PCB substrate.

FIG. 5 is a cross-sectional diagram illustrating the formation of a conductive via in a PCB substrate.

FIG. 6 is a schematic diagram illustrating the electroplating system used for forming conductive vias in a PCB.

FIG. 7 illustrates one example of the electroplating setup for forming conductive vias in a PCB.

FIG. 8 is a cross-sectional diagram illustrating the formation of a conductive via in a PCB substrate.

FIG. 9 is a cross-sectional view illustrating the formation of a conductive via in a PCB substrate.

FIG. 10 illustrates a cross-sectional view of a PCB substrate with a plated via and the removal of conductive tape.

FIG. 11 illustrates a cross-sectional view of the PCB at one stage of one method of plating a completed circuit board or device.

FIG. 12 illustrates a cross-sectional view of the PCB shown in FIG. 11 at another stage of the method of plating a completed circuit board or device.

FIG. 13 illustrates a cross-sectional view of the PCB shown in FIG. 11 at another stage of the method of plating a completed circuit board or device.

FIG. 14 illustrates a cross-sectional view of the PCB at one stage of another method of plating a completed circuit board or device.

FIG. 15 illustrates a cross-sectional view of the PCB shown in FIG. 14 at another stage of the method of plating a completed circuit board or device.

FIG. 16 illustrates a cross-sectional view of the PCB shown in FIG. 14 at another stage of the method of plating a completed circuit board or device.

FIG. 17 illustrates a cross-sectional view of the PCB at one stage of another method of plating a completed circuit board or device.

FIG. 18 illustrates a cross-sectional view of the PCB shown in FIG. 17 at another stage of the method of plating a completed circuit board or device.

FIG. 19 illustrates a cross-sectional view of the PCB shown in FIG. 17 at another stage of the method of plating a completed circuit board or device.

FIG. 20 illustrates a cross-sectional view of the PCB shown in FIG. 17 at another stage of the method of plating a completed circuit board or device.

FIG. 21 illustrates a finished device with conductive vias formed in a PCB substrate.

FIG. 22 is a flow chart diagram illustrating a method for forming conductive vias in a PCB substrate.

### DETAILED DESCRIPTION

In the field of printed circuit board (PCB) fabrication, the formation of conductive vias plays a significant role in establishing electrical interconnections among electronic components. Traditional methods for forming conductive vias typically involve mechanical or laser drilling to create through holes, followed by extensive chemical cleaning and preparation of the drilled openings. These processes often require multiple sequential steps, including desmearing, plasma cleaning, and micro-etching, to ensure the interior surfaces of the vias are adequately prepared for metallization. Such arrangements contribute to longer cycle times, elevated manufacturing costs, and the need for careful handling of hazardous substances.

The disadvantages of existing methods are numerous. Firstly, the reliance on chemical cleaning and preparation steps introduces significant inefficiencies into the manufacturing process. These steps not only increase the time required to produce PCBs but also necessitate the use of caustic or dangerous chemicals, raising operational and environmental concerns. Additionally, the complexity of these processes can lead to variable performance, particularly when precise conformality of the metallized layer is desired. The intricate balance between adequately preparing the via surfaces and avoiding excessive treatment can restrict the efficiency with which conductive layers are deposited, leading to inconsistent electrical characteristics. Furthermore, the need for extensive cleaning and chemical activation methods may not yield uniformly conductive layers, especially in the case of extremely small or high aspect-ratio vias.

The present approach addresses these challenges by introducing a streamlined method for forming conductive vias in printed circuit boards. This novel technique significantly reduces the time, labor, and chemical usage compared to traditional techniques. The method utilizes mechanical drilling or laser drilling to create through holes that may naturally possess nucleation sites for electroplating due to the formation of a heat-affected zone. This zone may become partially carbonized, providing a conductive film that facilitates direct electroplating without the need for a conductive seed layer or chemical cleaning. Additionally, the laser drilling method may generate copper dust that further enhances nucleation sites, allowing for efficient electroplating. The process is adaptable for both small batch and large-scale production, offering a rapid and environmentally friendly alternative to existing methods.

Systems and methods for forming conductive vias in a printed circuit board are provided. These systems and methods use a mechanical or laser drilling process that creates a heat-affected zone along the interior surfaces of the through hole. This zone may become partially carbonized, forming a thin carbon film that may serve as nucleation sites for electroplating. The system and method immerse the printed circuit board in a plating bath containing a metal ion solution and electroplate the interior surfaces of the through hole by applying an electrical current.

This approach reduces or eliminates the need for traditional chemical cleaning and preparation steps, which are typically required to ensure the interior surfaces of the vias are adequately prepared for metallization. By forming a heat-affected zone that may naturally provides nucleation sites, the method reduces the number of processing steps, thereby decreasing cycle times and manufacturing costs. The carbonized film that may be created during drilling may act as a conductive layer, which may facilitate direct electroplating without the need for a conductive seed layer. This not only simplifies the process but also minimizes the use of hazardous chemicals, addressing environmental and operational concerns. The system and method are adaptable for both small batch and large-scale production, offering a rapid and efficient alternative to existing techniques. Additionally, the ability to form nucleation sites directly during the drilling process enhances the uniformity and reliability of the conductive vias, improving the electrical performance of the printed circuit board.

In the context of technical and scientific descriptions, “approximately” is used to indicate that a value or measurement is close to, but not exactly, a specified number. It acknowledges a degree of uncertainty or tolerance in the measurement, allowing for minor variations or deviations from the stated value. This term is often used when exact precision is not necessary or when slight variations are acceptable within the context of the application. For example, “approximately” means within manufacturing tolerances in one embodiment. In other embodiments, “approximately” means within 1%, within 3%, or within 5%.

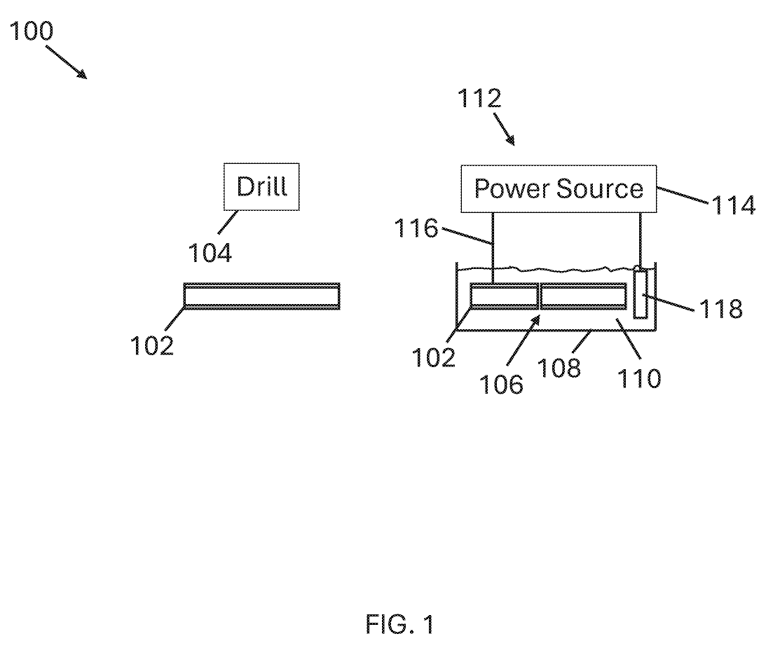

FIG. 1 illustrates one example of a conductive via forming system 100, which is designed to efficiently create conductive vias in PCB substrates. The system 100 integrates several components to streamline the process of drilling and electroplating through holes for forming conductive vias in the PCB substrates.

A printed circuit board (PCB) substrate 102 is typically composed of dielectric layers with conductive metal (e.g., copper) cladding. The substrate 102 is the target for the drilling and plating processes to form the conductive vias. A drill 104 can be either a mechanical drill or a laser drill. The drill 104 creates through holes 106 in the PCB substrate 102. The drilling process generates a heat-affected zone along the interior surfaces of the through holes 106, which may become partially carbonized to serve as nucleation sites for electroplating.

A container 108 holds an electroplating bath 110 and is sized to receive the PCB substrate 102 with the through hole(s) 106. The container 108 is sufficiently large to ensure that the substrate 102 is immersed in the plating solution or bath 110 for electroplating. The plating bath 110 contains a metal ion-containing plating solution, typically comprising copper ions, which facilitates the electroplating of the interior surfaces of the through hole(s) 106. The solution 110 may include additives such as surfactants to enhance plating efficiency.

An electroplating device 112 applies an electrical current (e.g., a potential, such as direct current) to the PCB substrate 102, enabling the deposition of metal from the plating solution 110 onto the nucleation sites within the through hole 106. A power source 114 of the electroplating device 112 provides the electrical current for the electroplating process, ensuring that metal ions from the plating bath 110 are deposited onto the interior surfaces of the through hole(s) 106.

A cathode 116 of the electroplating device 112 is electrically coupled to the PCB substrate 102, such as one or more of the conductive cladding layers of the PCB substrate 102. The cathode 116 assists with conducting current through the substrate 102 and into the plating bath 110 to initiate electroplating. An anode 118 of the electroplating device 112 is immersed in the plating bath 110 and serves as the source of metal ions for the electroplating process. The anode 118 releases metal ions into the solution, which are then deposited onto the interior surfaces of the through hole 106 to form the conductive vias. The anode 118 can be formed from copper, for example.

The drill 104 forms the through holes 106 in the PCB substrate 102. The drill 104 can be implemented as either a mechanical drill or a laser drill, each offering distinct advantages depending on the specific requirements of the PCB fabrication process. The mechanical drill can rotate and contact the PCB substrate 102 to mechanically cut the PCB substrate 102 to form the through holes 106. The laser drill can emit laser light into the PCB substrate 102 and remove portions of the PCB substrate 102 to form the through holes 106 without contacting the PCB substrate 102.

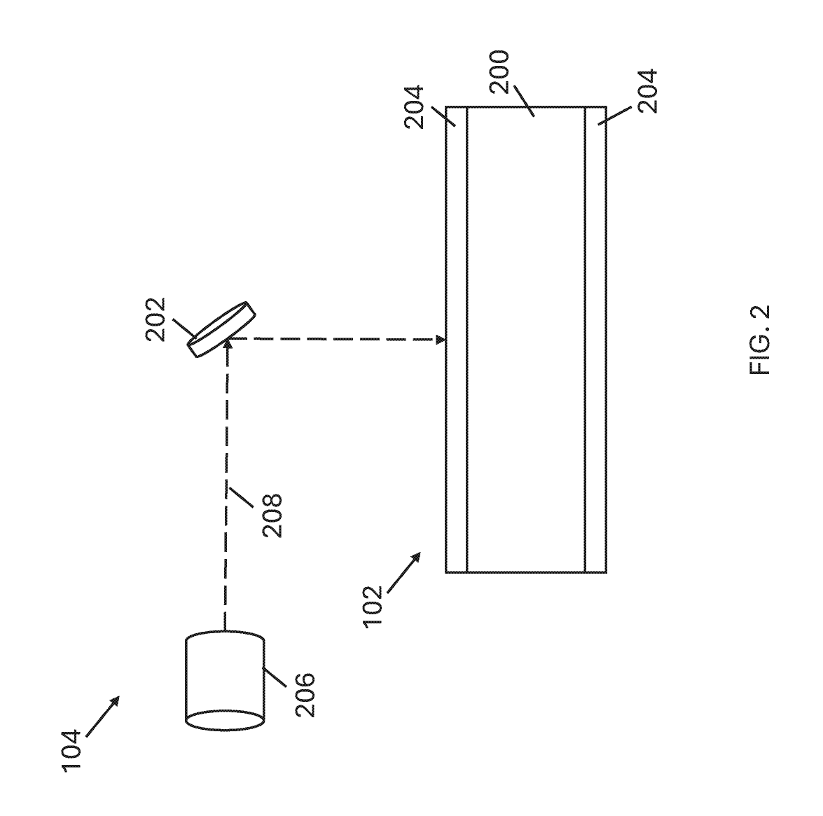

FIG. 2 is a schematic diagram illustrating the laser drilling process for forming through holes in a PCB substrate. In this example, the drill 104 represents or includes a laser 206 for creating the through holes 106 in the PCT substrate 102. The laser drill 206 is configured to deliver precise and controlled energy to the substrate 102, enabling the formation of the through holes 106 with high accuracy. The laser drill 206 is particularly effective for creating smaller through holes 106 and vias in high-density interconnect designs.

The laser 206 is a pulsed laser in one example. The laser 206 can emit laser beams 208 with specific to optimize the drilling process and reduce (or eliminate incidental) damage to the substrate 102. For example, the laser 206 can be a pulsed nanosecond 355 nanometer Q-switched laser with a pulse width of approximately 14 nanoseconds. The wavelength of 355 nm can provide advantages in forming the through hole with controlled material removal and localized modification of the side wall. A wavelength of 355 nm can enable efficient interaction with the substrate material so that the laser energy can be concentrated in a manner that supports precise ablation of the dielectric material and formation of the through hole with reduced impact on adjacent regions of the printed circuit board substrate. Use of the 355 nm wavelength can also support formation of the heat-affected region along the side wall, including carbonization of dielectric material that contributes to the partially conductive region used to initiate electroplating. Accordingly, the 355 nm wavelength can help balance through-hole formation, side-wall conditioning, and preparation of the through hole for subsequent electroplating.

The Q-switched laser with a pulse width of approximately 14 nanoseconds, can provide advantages in precision, controllability, and formation of the partially conductive side-wall region. The Q-switched configuration can deliver laser energy in short, high-intensity pulses that promote efficient material removal while limiting excessive heat spread into surrounding portions of the substrate 102. The approximately 14 nanosecond pulse width can provide a balance between effective ablation of the dielectric material and localized thermal modification of the side walls of the through hole, including carbonization that contributes to the partially conductive region used to initiate electroplating. The 355 nanometer wavelength can further improve coupling of the laser energy to the substrate material, which can support formation of the through hole with controlled geometry and consistent side-wall conditioning. Accordingly, use of a pulsed nanosecond 355 nanometer Q-switched laser can improve repeatability of via formation while also supporting direct electroplating of the through hole after laser processing.

Alternatively, the laser 206 may be another pulsed laser and/or wavelength (e.g., IR MOPA, IR Q-switched, etc.). The laser beam 208 is the focused energy emitted by the laser 206, and is directed toward the PCB substrate 102 to ablate material and form the through holes 106. The laser beam 208 is controlled to ensure precise ablation, creating a heat-affected zone that may serve as nucleation sites for subsequent electroplating.

Use of a pulsed laser 206 can provide several advantages during formation of the through holes 106. The pulsed laser 206 can deliver energy in controlled pulses that ablate material with greater precision, which can reduce incidental damage to the surrounding portions of the substrate 102 while still forming a heat-affected zone along the side walls 502 of the through holes 106. The pulse characteristics, including pulse width and wavelength, can be selected to promote localized thermal modification of the dielectric material, including carbonization that contributes to a partially conductive region along the side walls 502. The pulsed laser 206 can also be scanned according to a selected pattern, such as a bidirectional cross-hatch pattern, so that a relatively small laser spot can form a larger through hole while maintaining a dwell time sufficient to create the partially conductive region without excessive burning of the substrate 102. The pulsed laser 206 can further be used for a non-chemical cleanup pass at a higher scan speed to remove resin or glass melt from the side walls 502, which can reduce or eliminate reliance on conventional chemical cleaning and preparation steps before electroplating.

A galvo system 202 can direct and control movement of the laser beam 208 across the surface of the PCB substrate 102. The galvo system 202 represents one or more mirrors, motors, lenses, or the like, that can move to rapidly and precisely position and direct the laser beams 208. This allows the creation of through holes 106 in specific patterns or locations as required. Alternatively, a gantry system (as described herein) can be used to move the laser 206 to direct the laser beam 208 into desired locations for the through holes 106.

The PCB substrate 102 serves as the foundational material for the PCB, providing the structural support and dielectric properties necessary for electronic circuit integration. The substrate 102 includes a dielectric substrate or layer 200, such as an epoxy resin or fiberglass composite, sandwiched between bulk conductive layers 204, usually made of copper. There may be several substrates 200, and layers 204, such as four substrates 200 and pair of layers 204, six substrates 200 and pair of layers 204, or more. These conductive layers 204 facilitate electrical connectivity across the PCB substrate 102, while the dielectric substrate 200 provides insulation between different circuit layers.

The bulk conductive layers 204 provide the conductive pathways required for electrical signals within the PCB. Typically composed of copper, the bulk conductive layers 204 are bonded to the dielectric substrate 200 to form a composite structure that supports the functionality of the PCB. During the drilling process, the bulk conductive layers 204 may be partially ablated by the mechanical or laser drill 104, resulting in the formation of thin carbon layers and/or conductive dust that enhances the efficiency of the via formation process, as described below.

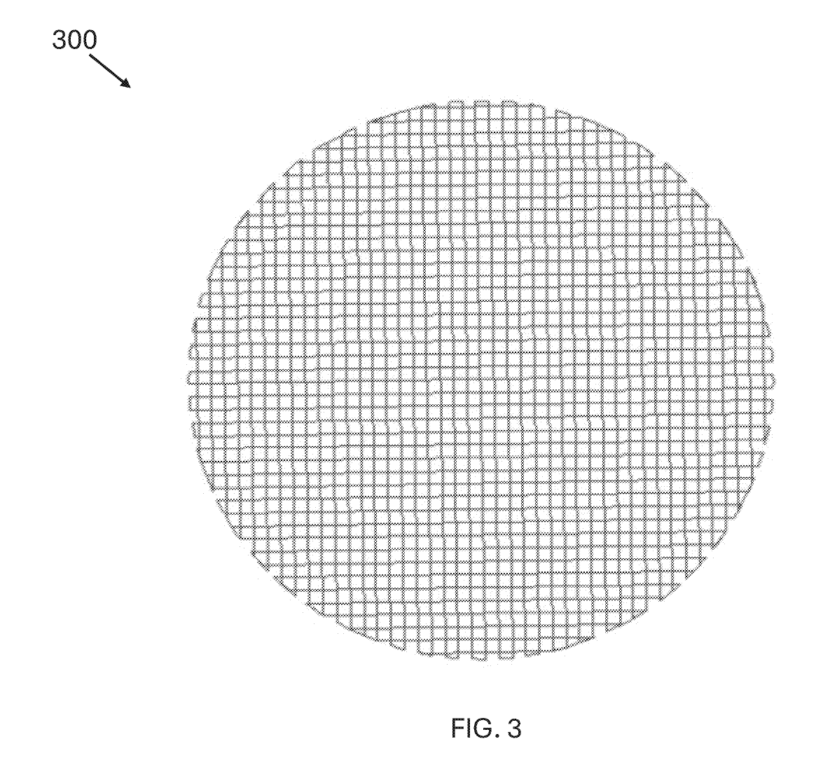

FIG. 3 illustrates a bidirectional cross hatch pattern 300 used in laser drilling for forming through holes 106. The bidirectional cross hatch pattern 300 can be used in the laser drilling process for forming the through holes 106 in the PCB substrate 102. Alternatively, another space-filling pattern or curve can be used, such as a unidirectional hatch pattern, a concentric hatch pattern, Hilbert curves, or the like. The pattern 300 allows the relatively small spot size of the laser 206 to drill significantly larger holes 106. The laser beam 208 follows this path 300, directed by the galvo system 202, to ablate the PCB substrate 102. In one example, a five watt average power laser 206 is moved at around 100 millimeters per second (mm/s) to 200 mm/s with a 40 kHz pulse frequency to drill the holes 106. Higher power figures can be used to speed up the drilling process. The movement speeds of the laser beam 208 of between 100 mm/s and 200 mm/s is a relatively long dwell time for the laser beam 208, which means the laser energy is being deposited for long enough to create the conductive layer (e.g., a carbonized layer) in the hole 106, but not so long that the laser beam 208 damages or burns a large area of the substrate 102. The laser 206 can direct the laser beam 208 into the hole 106 during a cleanup pass at a speed of approximately between 500 mm/s and 2,000 mm/s can be used during the drilling procedure to ensure the interior surfaces 502 of the substrate 102 are cleaned and any resin or glass melt is removed. Multiples of each cleanup pass or drilling pass may be necessary to drill the substrate 102 to the correct depth.

The pattern 300 is used to enhance the efficiency and precision of the laser drilling operation, particularly when dealing with small spot sizes of the laser beam 208. The bidirectional cross hatch pattern 300 allows the laser 206 to cover a larger area by systematically rastering the laser beam 208 across the substrate 102, ensuring that the entire surface is uniformly ablated. This technique is particularly useful for creating larger drill holes with a laser beam 208 that has a relatively small spot size, typically around 15-25 microns. By following this pattern 300, the laser 206 can effectively ablate the PCB substrate 102, creating through holes 106 that are consistent in size and shape, which is necessary for the subsequent electroplating process.

The implementation of the bidirectional cross hatch pattern 300 involves directing the laser beam 208 along a predetermined path using the galvo system 202 combined with a telecentric f-theta lens. This setup allows for precise control over the movement and positioning of the laser beam 208, ensuring that the pattern 300 is accurately followed. The bidirectional nature of the pattern 300 means that the laser 208 moves back and forth across the substrate 102, reducing the risk of uneven ablation and ensuring that the heat-affected zone is uniformly distributed along the interior surfaces of the through holes 106. This uniformity is beneficial for potentially forming a consistent carbonized film that may serve as nucleation sites for electroplating, as described herein. The pattern 300 also helps prevent smearing and fiberglass melting effects, which can occur if the laser energy is not evenly distributed. By utilizing the bidirectional cross hatch pattern 300, the laser drilling process can be optimized to create through holes 106 that are immediately ready for electroplating, without the need for additional cleaning or preparation steps.

In the pattern 300, the galvo system 202 directs the laser beam 208 along a first direction (e.g., a linear path extending to the right in FIG. 3 until the laser beam 208 reaches an edge of the area where the through hole 106 is being formed, then turns and moves slightly downward or upward in FIG. 3 before moving to the left. The laser beam 208 is directed along this direction until reaching the opposite side of the area where the through hole 106 is being formed, and then turns and moves slightly up or down. The laser beam 208 can continue to move in this pattern 300 until all left and right paths in the pattern 300 are formed. The galvo system 202 can then move the laser beam 208 in up and down directions in a similar way and as shown in FIG. 3 to complete the pattern 300.

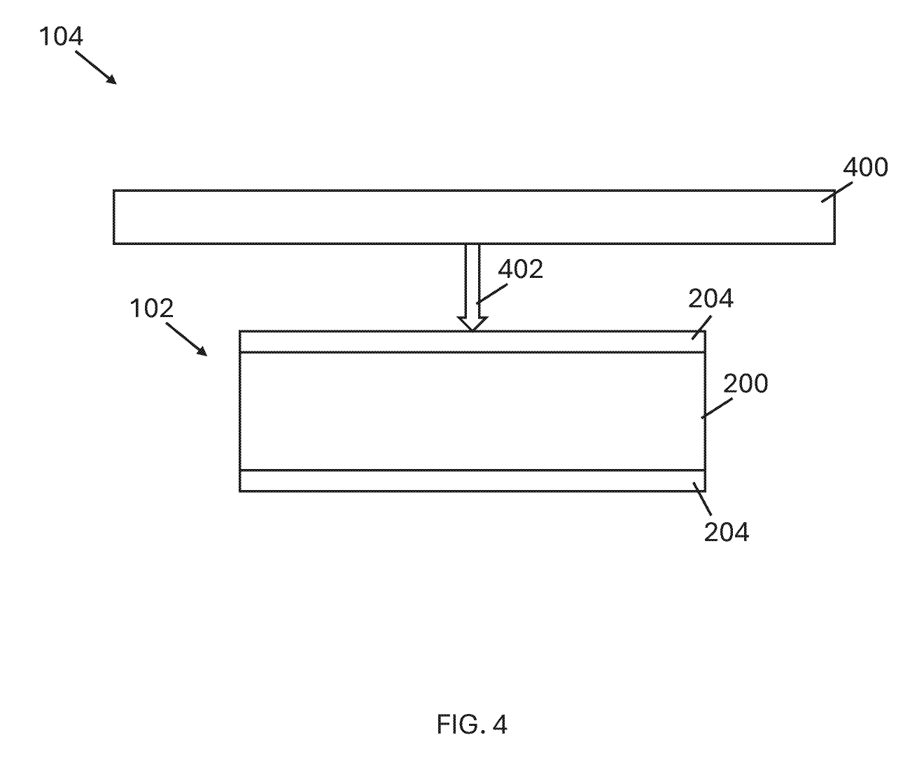

FIG. 4 illustrates the mechanical drilling process for forming the through holes 106 in the PCB substrate 102. The drill 104 can represent or include a mechanical drill 402 to cut the through holes 106 through the substrate 102. The mechanical drill 402 operates by physically cutting through the substrate material using a rotating drill bit. This type of drill is typically employed for creating larger through holes 106 compared with the laser 206.

A gantry system 400 supports and guides the drill 104, ensuring precise alignment and movement during the drilling process. The gantry system 400 includes motors, belts, tracks, etc. that move the drill 104 to different locations to drill the through holes 106 in different locations. The system 400 allows for controlled movement of the drill 104 across the surface of the PCB substrate 102, enabling the creation of through holes 106 in specific patterns or locations as required. The system 400 can be a computer numerical control (CNC)-based system in one example. The system 400 can be adapted to different drilling technologies and PCB designs, enhancing the overall efficiency and effectiveness of the via formation process.

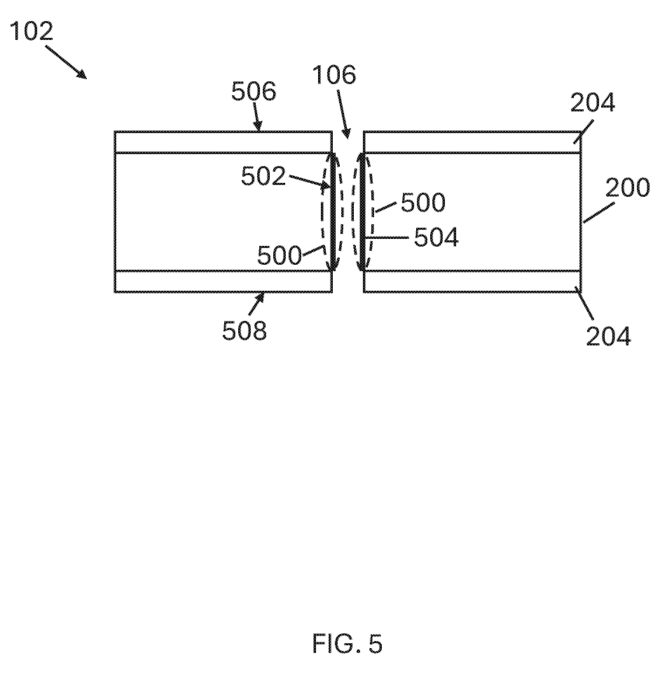

FIG. 5 is a cross-sectional diagram illustrating the formation of a through hole 106 in the PCB substrate 102. The through hole 106 is cut through the entire thickness of the PCB substrate 102 by the drill 104. Alternatively, the drill 104 cuts the through hole 106 through part, but not the entire, thickness of the PCB substrate 102. The through hole 106 serves as a conduit for electrical connections between different layers of the PCB.

The formation of the through hole 106 is accompanied by the creation of a heat-affected zone 500 along interior surfaces 502 of the PCB substrate 102. These surfaces 502 can be the boundary of the through hole 106 provided by the PCB substrate 102. The interior surfaces 502 can be heated and partially carbonized during laser drilling and/or during mechanical drilling. This can form a thin layer 504 of carbon or carbonized film on the interior surfaces 502 of the through holes 106. The layer 504 may be continuous or may have one or more gaps or spaces. As another example, the drilling through the conductive layer(s) 204 can create conductive dust that scatters with some dust landing on the interior surfaces 502 of the through holes 106. The thin layer 504 can represent this conductive dust.

The pulsed laser can form the partially conductive region that provides a significant advantage by creating an electrically active path on the side wall as part of the drilling operation itself, rather than requiring a separate conductive seed deposition process. The carbonized dielectric material can increase conductivity along the side wall, while the deposited metal dust can provide additional conductive sites that promote initiation and continuation of electroplating. As a result, the through hole can become sufficiently conductive to support electroplating directly after laser formation, which can reduce or eliminate reliance on conventional desmear, chemical cleaning, or electroless copper seeding operations. Additionally, because the partially conductive region is formed in situ during laser drilling, the process can simplify manufacturing flow, reduce processing time, and improve alignment between the drilled through hole and the conductive region used to initiate plating.

Due to the nature of the short pulse width of the laser beam 208, the heat affected zone 500 is extremely thin, only penetrating the very surface of the side walls 502 of the hole 106. The heat causes a thin layer 504 of conductive material to form from the substrate 102, likely carbon being formed. Additionally, as the laser beam 208 ablates the lower layers 204 of the copper clad laminate (e.g., the substrate 102), the laser beam 208 eventually begins to ablate the lower copper layers 204. As the copper is ablated away, some of the ejected copper dust is embedded on the surface 502 of the walls of the hole 106. These two phenomena combined create vias that can have resistances ranging from a few hundred ohms to a few thousand or hundred thousand ohms.

In some examples, the thin layer 504 of conductive material formed on the side walls 502 of the through holes 106 is produced at least in part from the dielectric material of the substrate 102 disposed or located between the conductive layers 204, rather than being produced from the conductive layers 204 themselves. For example, when the substrate 102 includes an FR-4 dielectric material, the heat from the laser beam 208 can carbonize a relatively thin surface region of the dielectric material along the side walls 502 of the through holes 106 while leaving the surrounding substrate structure substantially intact. The FR-4 dielectric material can provide advantages in manufacturability, structural stability, and compatibility with the disclosed via-formation process. FR-4 can provide sufficient mechanical strength and dimensional stability to support formation of through holes and subsequent electroplating operations, while also being compatible with conventional printed circuit board fabrication processes and materials. Additionally, when exposed to the pulsed laser under selected operating conditions, the FR-4 dielectric material can form a heat-affected region along the side walls of the through holes that includes carbonized material contributing to the partially conductive region used to initiate electroplating. Accordingly, use of FR-4 can support both reliable substrate performance and implementation of the disclosed laser-based formation of conductive vias.

The resulting partially conductive region extends substantially continuously through the thickness of the substrate 102 along the side walls 502 of the through holes 106. This continuity or substantial continuity can provide an electrically connected path between opposite surfaces of the substrate 102 before bulk electroplating is completed. This promotes more uniform initiation and growth of plated conductive material within the through holes 106. The partially conductive region can be formed by laser-induced thermal modification of the dielectric material adjacent the side walls 502, such that localized carbonization or other conductivity-enhancing transformation occurs along substantially the full depth of each through hole 106. This substantially continuous conductive path can facilitate current flow during electroplating and can reduce discontinuities that might otherwise inhibit reliable buildup of plated material through the thickness of the substrate 102. As used herein, “substantially continuously” means continuously enough along the thickness of the substrate 102 to permit electroplating current to propagate through the through hole 106 and initiate plated conductive buildup along the side walls 502, even if isolated microscopic discontinuities, variations in conductivity, or local interruptions are present.

This thin conductive layer 504 is only created under specific circumstances with proper laser settings, and is not created by traditional end mill routing. In traditional laser drilling, the lasers are tuned to prevent any kind of build-up inside or on the via walls, instead attempting to mimic the clean holes of an end-mill routed hole. Additionally, lasers have traditionally only been used for micro-drilling rather than entire boards. Finally, any conductive layer that could accidentally be created by a traditional laser drill is destroyed in the ensuing PCB processing steps, e.g. desmear, plasma cleaning, micro-etch, etc.

Though this drilling process is not enough to form a functional via using the conductive layer 504, the thin conductive layer 504 created by the laser 206 may be conductive enough to act as a seed layer for electroplating. The layer 504 of carbonized material and/or conductive dust may provide conductive areas or locations that provide nucleation sites for electroplating conductive material on the interior surfaces 502 of the through holes 106 for forming the conductive vias. This process eliminates the need for traditional chemical cleaning and preparation steps, as the layer 504 acts as a conductive layer, facilitating direct electroplating without the need for a conductive seed layer to be added to the interior surfaces 502. That is, the through hole(s) 106 can be drilled and then electroplated with metal to form the conductive vias, without applying any chemicals to the interior surfaces 502 to clean and remove the carbonized material and/or conductive dust between drilling the through hole 106 and electroplating the through hole 106. The substrate 102 can be immediately taken out of the laser drilling machine and placed directly into the electroplating bath 110. Here, current is passed through a bulk copper anode and into the conductive vias, where a thick layer of copper can be plated on the conductive layer 504, as described below.

The first side 506 and the second side 508 of the printed circuit board substrate 102 represent the two opposing surfaces of the substrate through which the through hole 106 is drilled from one side 506 to (and through) the other side 508. Alternatively, the through hole 106 may be drilled only partially through from one side 506 or 508 partially to, but not completely to or through, the other side 508 or 506. These sides 506, 508 are typically covered with bulk conductive layers 204, which facilitate electrical connectivity across the PCB. The drilling process creates a pathway between these two sides 506, 508, allowing for the formation of conductive vias that establish electrical interconnections between different layers of the PCB.

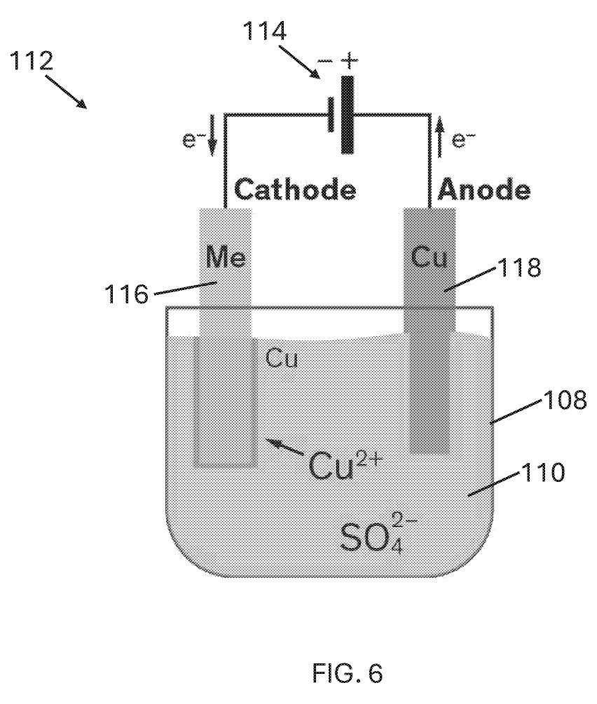

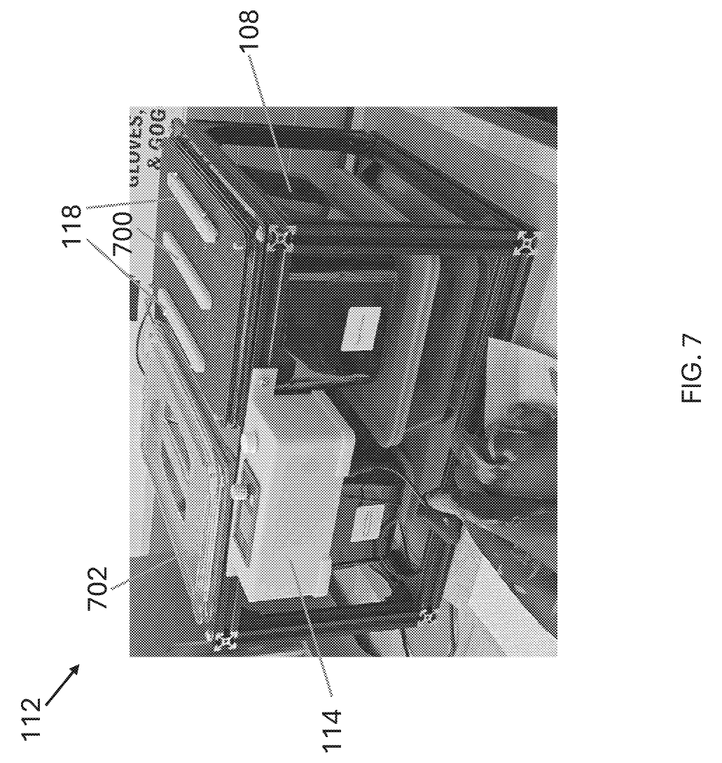

FIG. 6 is a schematic diagram illustrating the electroplating device 112 used for forming conductive vias in the PCB substrate 102. FIG. 7 illustrates one example of the electroplating device 112. The electroplating device 112 facilitates the electroplating process, which involves depositing metal onto the interior surfaces 502 of the substrate 102 around the through holes 106 formed in the substrate 102. The electroplating device 112 is electrically connected to the substrate 102 (such as to at least one or both of the conductive layers 204), allowing the application of an electric current used for the deposition of metal ions from the plating solution 110 onto the nucleation sites potentially provided by the layer 504 in the heat-affected zone 500. This device 112 is designed to ensure uniform metal deposition, which helps create reliable and conductive vias. The electroplating device 112 includes the power source 114, such as a battery, utility grid, or the like, to conduct current between and through the cathode 116 (which can be coupled with or conductively coupled with the conductive layer(s) 204 of the substrate 102) and the anode 118 (a sacrificial metal body, such as a copper or copper alloy body). The cathode 116 and anode 118 complete the electroplating circuit, thereby enabling the efficient transfer of metal ions from the plating bath 110 and/or anode 118 to the interior surfaces 502 of the through holes 106.

The power source 114 is connected to both the cathode 116 and the anode 118, establishing an electrical circuit that facilitates the movement of electrons and metal ions within the plating bath 110. The power source 114 delivers a stable and controlled current to ensure consistent plating results. The cathode 116 serves as the negative electrode in the electrochemical circuit. The cathode 116 is electrically coupled to the PCB substrate 102, providing a pathway for electrons to flow from the power source 114 into the plating bath 110. This coupling can occur before immersing (e.g., submerging) the PCB substrate 102 in the plating bath 110, while the PCB substrate 102 is lowered into the plating bath 110, or after the PCB substrate 102 is in the plating bath 110. The cathode 116 attracts positively charged metal ions from the plating solution 110, facilitating deposition of these ions onto the interior surfaces 502 of the through holes 106. This deposition process forms the conductive vias, as the process builds up a layer of metal on the interior surfaces 502 of the through holes 106 that enhances electrical connectivity across the printed circuit board.

The anode 118 serves as the positive electrode in the electroplating system, immersed in the plating bath 110 to release metal ions into the solution 110. The anode 118 connects to the power source 114, completing the electrical circuit used for the electroplating process. The anode 118 can be composed of the same metal that is being deposited onto the interior surfaces 502 of the through holes 106, such as copper, ensuring a consistent supply of metal ions for plating. The anode 118 replenishes the metal ions in the plating solution 110 as the ions are deposited onto the cathode 116 and the interior surfaces 502 of the through holes 106.

The container 108 holds the plating bath 110, which contains the metal ion-containing plating solution required for the electroplating process. The container 108 is sized to accommodate the substrate 102 and the electroplating components, ensuring that the substrate 102 is fully immersed in the plating solution 110. The construction of container 108 involves materials that are resistant to the chemical composition of the plating bath 110, preventing any adverse reactions that could affect the plating process. The design may include features such as agitation mechanisms to maintain uniform distribution of metal ions within the solution, enhancing the efficiency and consistency of the electroplating process.

The plating bath 110 is a solution containing metal ions, typically copper ions, for the electroplating process. The solution 110 is housed within the container 108 and serves as the medium through which metal ions are transferred from the anode 118 to the cathode 116 and the interior surfaces 502 of the through holes 106. The composition of the plating bath 110 may include additives such as surfactants to improve plating efficiency and ensure uniform deposition across all through holes 106. The concentration of metal ions and other chemical components in the plating bath 110 requires careful control to achieve optimal plating results, as variations can impact the quality and conductivity of the vias. The plating bath 110 plays a significant role in the system, enabling the formation of conductive vias that enhance the electrical performance of the printed circuit board.

In some examples, the plating bath 110 includes copper sulfate, sulfuric acid, hydrochloric acid, sodium chloride, deionized water, and a surfactant. The surfactant can include polysorbate-20, which can reduce surface tension and assist the plating bath 110 in entering relatively small through holes 106 or through holes 106 having relatively high aspect ratios. The concentration of sulfuric acid and hydrochloric acid can be selected to facilitate plating within through holes 106 having relatively high aspect ratios. This plating bath composition can be advantageous because the combination of copper sulfate, sulfuric acid, hydrochloric acid, sodium chloride, deionized water, and a surfactant can promote stable copper ion availability and improved solution transport within the through holes 106 during electroplating. Inclusion of polysorbate-20 can reduce surface tension so that the plating bath 110 more readily wets and penetrates relatively small through holes 106 or through holes 106 having relatively high aspect ratios, which can improve plating initiation and reduce the likelihood of unplated regions caused by poor solution access. Selection of the concentration of sulfuric acid and hydrochloric acid to facilitate plating within relatively high-aspect-ratio through holes 106 can further improve current conduction and metal deposition along the depth of the through holes 106. As a result, the disclosed bath chemistry can support more reliable via formation, greater process robustness across varying hole geometries, and reduced likelihood of incomplete plating as compared with processes that are less tailored for penetration and deposition within narrow or deep through holes 106.

In FIG. 7, the container 108 holding the plating bath 110 is enclosed with two slots in which the anode 118 is placed and a board slot 700 in which the PCB substrate 102 is placed. The board slot 700 ensures that the substrate 102 is properly positioned and immersed in the plating bath 110, allowing for uniform exposure to the plating solution. The board slot 700 is constructed to accommodate various sizes and thicknesses of PCB substrates 102, providing flexibility in the electroplating process. By maintaining the correct orientation and immersion depth, the board slot 700 helps ensure that the electroplating process is consistent and effective across the entire surface of the board 102.

The electroplating device 112 can include an ion sequestration container 702. The ion sequestration container 702 holds another bath that is utilized after the plating is completed, to clean a plated PCB substrate 102 of any soluble copper ions that are still clinging to the surface of the PCB substrate 102 after removal from the plating bath 110. The ion sequestration bath turns the soluble copper ions into insoluble copper carbonate (or another insoluble copper compound), which is easier to dispose of or discard, and poses less risk to the environment than other disposals of the copper ions. The ion sequestration bath within the ion sequestration container 702 can include a sodium carbonate solution that converts soluble copper ions remaining on the substrate 102 after plating into an insoluble copper compound. Usage of a sodium carbonate solution in the ion sequestration container 702 can convert residual soluble copper ions remaining on the substrate 102 after plating into an insoluble copper compound that is less likely to remain mobile on the substrate surfaces 506, 508 or within surrounding process equipment. This can improve post-plating cleanliness and reduce the likelihood that residual copper ions will contribute to unwanted staining, contamination, or unintended deposition during subsequent handling or processing. By converting the residual copper ions into a more stable insoluble form, the ion sequestration bath can also simplify post-plating cleanup and improve overall process control, particularly in manufacturing flows in which the substrate 102 is moved promptly from plating to subsequent operations.

The conductive or partially conductive nucleation sites potentially provided by the carbonization and/or conductive dust are conductive, and consequently provide locations for the metal ions to nucleate. Small clusters or nuclei of metal atoms first begin to form on these nucleation sites. Nucleation occurs when the metal ions in the plating solution 110 are reduced at the surface of the nucleation sites, leading to the formation of these atomic clusters. The heat-affected zone created during drilling provides nucleation sites due to the formation of a carbonized film or conductive dust. Once nucleation occurs, the metal layer 800 begins to grow as more metal ions are reduced and deposited. The initial nucleation phase is crucial for determining the structure and properties of the final plated layer.

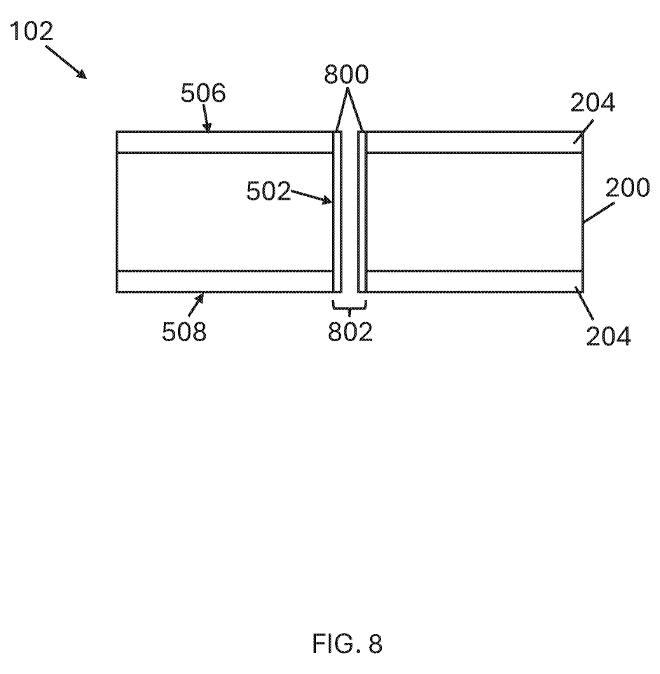

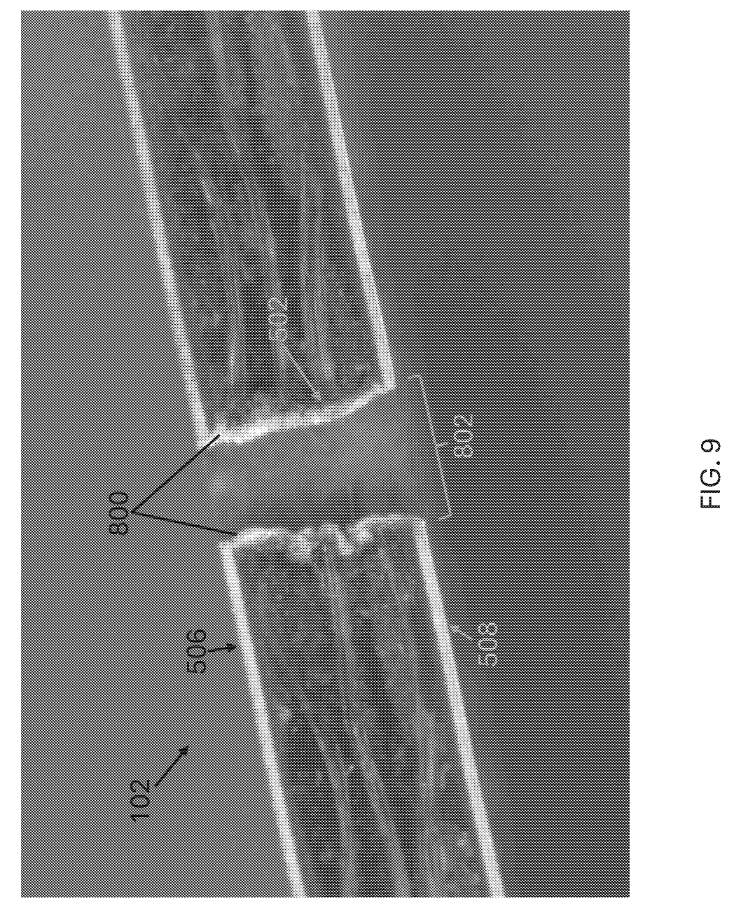

FIG. 8 is a cross-sectional schematic diagram illustrating one example of the formation of a conductive via 802 in the PCB substrate 102 formed by the electroplating device 112. FIG. 9 illustrates one example of a conductive via 802. The vias 802 are shown in cross-section. While the vias 802 are shown as cylindrical conduits or channels, the vias 802 may have another shape, such as 3D cylindrical structures through the PCB surface. The electroplating process forms one or more conductive layers 800 on the interior surfaces 502 of the through holes 106. This layer 800 establishes electrical connectivity between the conductive layers 204 on the first side 506 and the second side 508 of the PCB substrate 102. The layer 800 may be formed from copper or copper alloy, which is deposited from the plating solution 110 onto the nucleation sites provided by the carbonized film or conductive dust in the through hole 106.

The conductive via 802 represents the concluding structure formed within the PCB substrate 102, offering a pathway for electrical signals between various layers of the PCB. The via 802 is created by depositing the conductive layer 800 onto the interior surface 502 of the through hole 106, a process facilitated by the nucleation sites formed during the drilling process. The conductive via 802 plays a significant role in the PCB, as the via 802 allows for the integration of complex electronic circuits by establishing reliable electrical connections across multiple layers.

In one example, the PCB substrate 102 is first drilled to form the through holes 106 and then plated to form the conductive vias 802 before any circuit designs are put onto or formed on the PCB substrate 102. A copper clad laminate can be the PCB substrate 102 that is drilled with the laser 206. Once drilled, the PCB substrate 102 is directly placed into the plating bath 110 to be plated and form the vias 802. The copper of the laminate in the substrate 102 is acting as the connection to the cathode 116 in the plating solution 110. This conductively couples the partially conductive through holes 106 (e.g., the conductive or partially conductive layers 504) to the negative terminal of the power supply 114.

To reduce usage of the copper anode 118, before drilling the substrate 102 with the laser 206, a non-conductive adhesive sheet can be placed on top of each side 506, 508 of the copper clad 204 on the substrate 102. Once drilled, when the PCB substrate 102 is placed in the plating bath 110, the adhesive sheet covers the PCB substrate 102, and only the partially conductive drilled holes 106 are exposed to the plating bath 110. This causes the copper from the solution 110 and/or anode 118 is only plated onto the surface 502 of the holes 106, and not the entire PCB substrate 102 (e.g., outside of the holes 106). This reduces the amount of anode 118 that is consumed during plating the vias 802. Alternatively, the copper clad 204 can remain uncovered, allowing both the surfaces 506, 508 of the substrate 102 and the through holes 106 to be plated. By covering the surfaces 506, 508 of the substrate 102 and leaving the partially conductive drilled holes 106 exposed, the area available for plating is reduced, which can increase current density at the through holes 106 and increase the plating rate within the through holes 106 during an initial portion of the electroplating process.

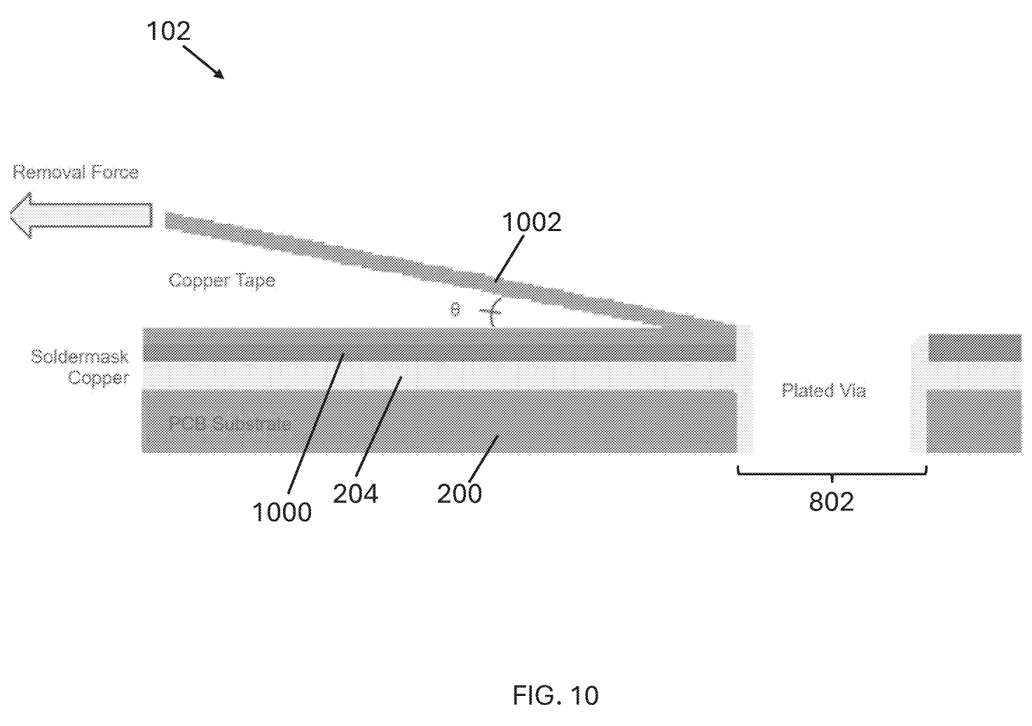

In another example shown in FIG. 10, the copper clad laminate 204 is etched to form circuit designs or circuits on the substrate 102. After this, the top and bottom surfaces 506, 508 are covered by a non-conductive layer or adhesive layer 1000, referred to as a solder mask in FIG. 10. This non-conductive layer or adhesive layer 1000 is then covered by a thin non-conductive layer or sticker 1004, such as a 1 mil thick polyimide or kapton tape layer followed by a conductive layer (e.g., a 1 mil thick copper tape layer) or sticker 1006 and, optionally, another thin non-conductive layer or sticker 1008. Forming the circuit designs or circuits on the substrate 102 before drilling and plating the through holes 106 can be advantageous because immersion of the substrate 102 in the plating bath 110 can introduce moisture into the substrate 102, which may make later etching more difficult unless an additional drying operation is performed.

The through holes 106 are then cut through the substrate 102. After this drilling, the substrate 102 is placed in the plating bath 110 and the vias 802 are formed by plating. The conductive layer 1002 provides the connection to the cathode 116 in the solution 110, thereby connecting the partially conductive films 504 in the through holes 106 to the negative terminal of the power supply 114.

To reduce usage of the copper anode 118, a non-conductive adhesive sheet can be placed on top of each side of the conductive layer 1002 (e.g., on each side of the substrate 102) before drilling the through holes 106. Once the holes 106 are drilled, the adhesive sheet covers the conductive layer 1002 when the PCB substrate 102 is placed in the plating bath 110. Only the partially conductive layers 504 inside the drilled holes 106 are exposed to the plating bath 110. As a result, copper is only plated onto the surface 502 of the holes 106, and not the entire PCB substrate 102. This is useful to limit anode consumption during plating.

In some examples, the non-conductive adhesive sheet disposed or located over the conductive layer 1002 remains in place during an initial portion of the electroplating process, after which the PCB substrate 102 is returned to the plating bath 110 for continued plating. This staged plating process can combine reduced anode 118 consumption and increased current density at the through holes 106 during the initial portion of plating with broader metal deposition during a later portion of plating.

Continued plating onto the conductive layer 1002 can improve bonding between plated material in the through holes 106 and conductive material adjacent upper regions of the through holes 106, which can facilitate cleaner removal of the conductive layer 1002 after plating. In some examples in which a non-conductive sheet is applied directly over the conductive layers 204 of the substrate 102, removal of the non-conductive sheet before plating is complete exposes the conductive layers 204 to the plating bath 110 so that continued plating improves bonding in annular regions adjacent the through holes 106 and increases via stability.

After plating, the board 102 is removed from the bath 110. The non-conductive adhesive and the conductive layer 1002 are then peeled back from the PCB’s surface, as shown in FIG. 10. When removing the conductive layer 1002, the layer 1002 is pulled from the surface at as close to 90 degrees as possible to allow the vias 802 to peel back from the layer 1002. The angle theta (θ) shown in FIG. 10 is as close to zero as possible in one example. Some small amount of abrasive processing, e.g. a light pass with sandpaper, can be used to remove any excess copper sitting above the board surface.

The conductive via 802 represents the completed structure formed within the printed circuit board substrate 102, providing a pathway for electrical signals between various layers of the PCB 102. The via 802 is created by depositing the conductive layer onto the interior surface 502 of the through hole 106, a process facilitated by the nucleation sites formed during the drilling process. The conductive vias 802 play a significant role in the PCB 102, as the vias 802 enable the integration of complex electronic circuits by establishing reliable electrical connections across multiple layers.

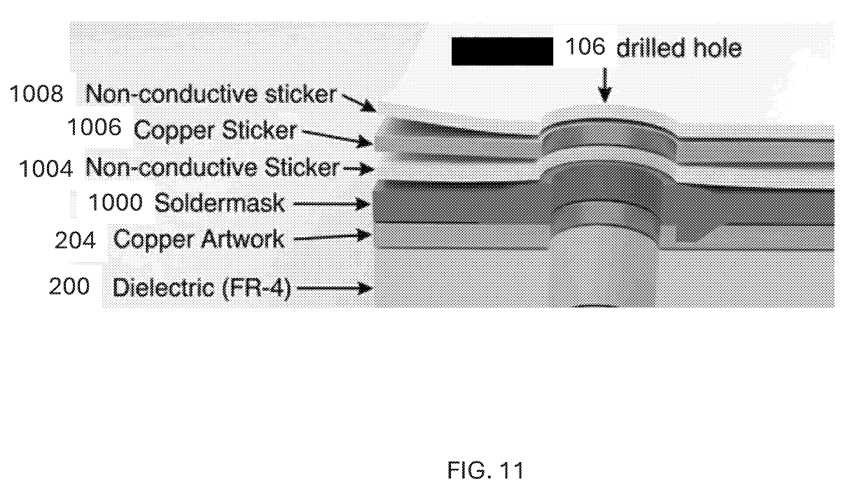

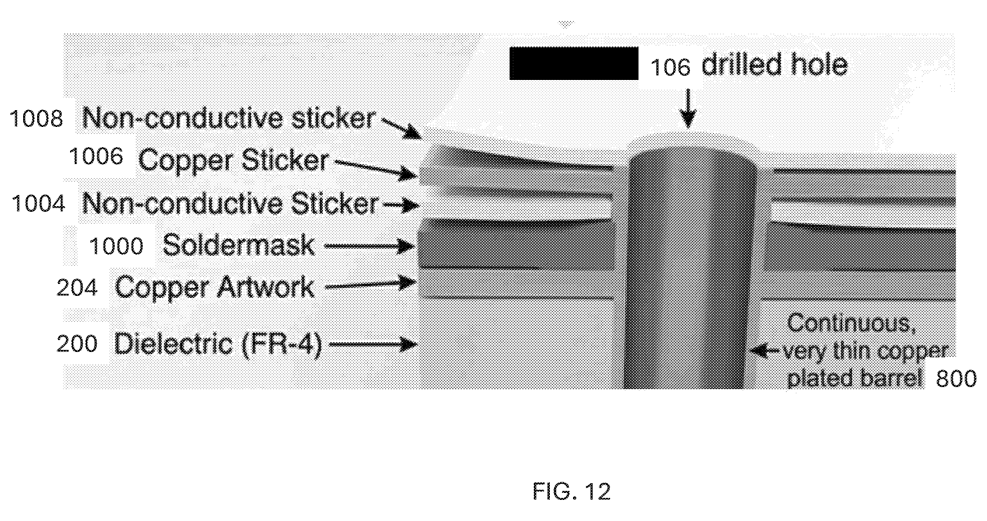

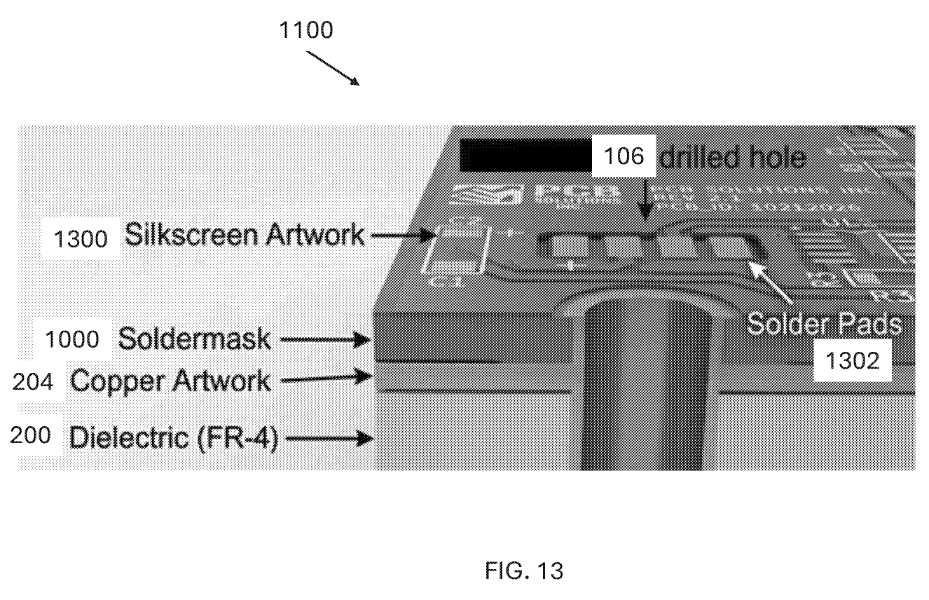

FIGS. 11 through 13 illustrate cross-sectional views of the PCB 102 at different stages of one method of plating a completed circuit board or device 1100. In FIG. 11, the PCB 102 is shown as including the dielectric layer 200 and one of the conductive layers 204. The solder mask 1000 is on the conductive layer 204, with the non-conductive sticker 1004 on the solder mask 1000 and the conductive sticker 1006 is on the non-conductive sticker 1000, and another non-conductive sticker 1008 on the conductive sticker 1006. The laser drill 104 cuts the hole 106 through all these layers 200, 204, solder mask 1000, and stickers 1004, 1006, 1008. As shown in FIG. 12, the electroplating bath forms the metal layer 800 along the exposed surfaces inside the hole 106. Once this plating is completed (shown in FIG. 13), the entire stack of the non-conductive stickers 1004, 1008 and the conductive sticker 1006 are removed or peeled away, leaving a completed circuit board 1100 with a silkscreen 1300 and solder pads 1302 exposed and shown in FIG. 13.

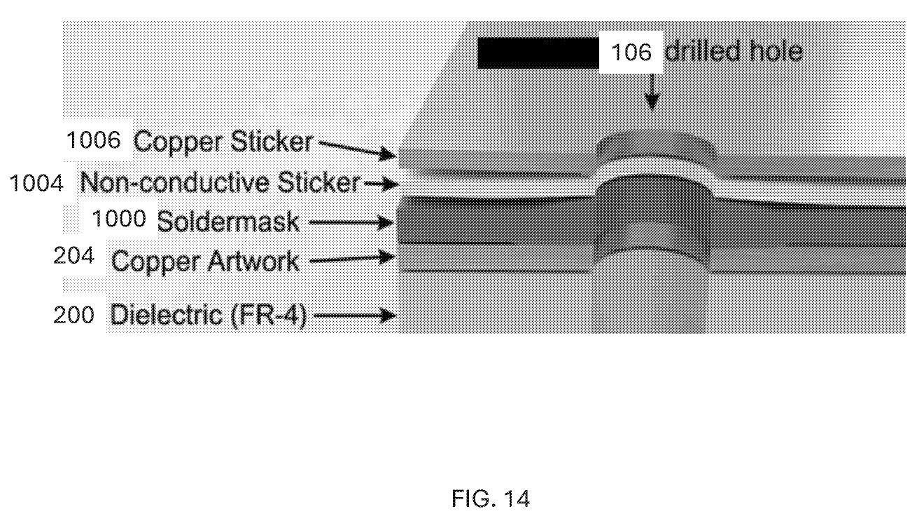

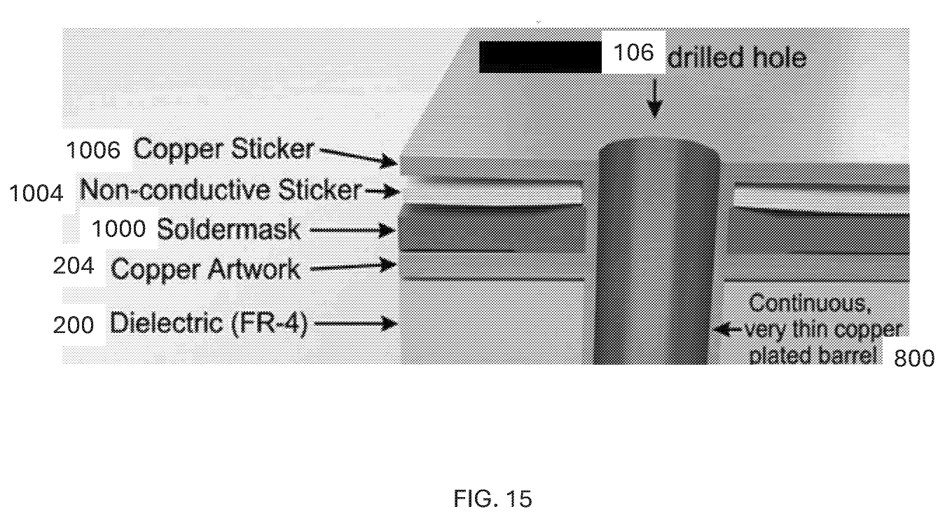

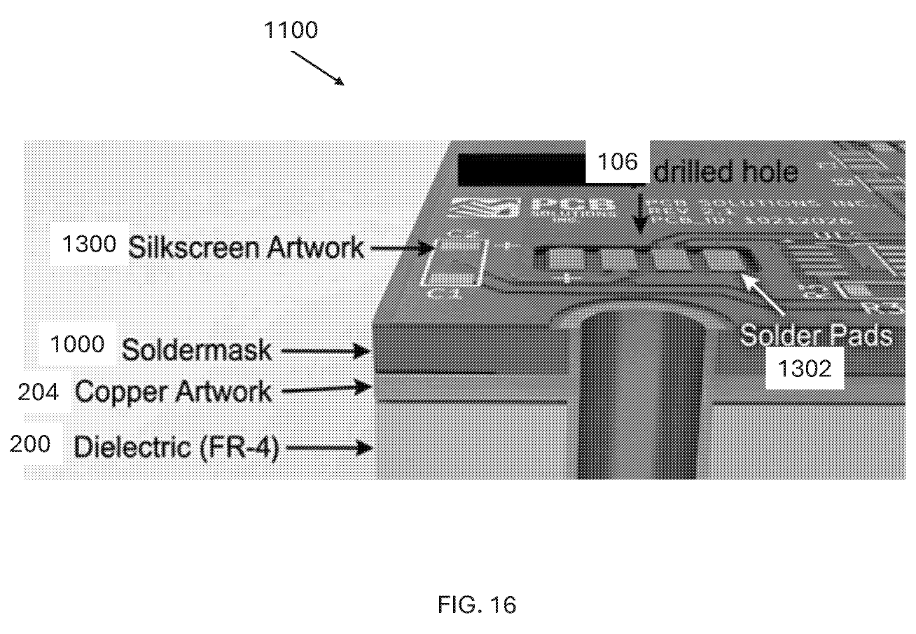

FIGS. 14 through 16 illustrate cross-sectional views of the PCB 102 at different stages of another method of plating a completed circuit board or device 1100. In FIG. 14, the PCB 102 is shown as including the dielectric layer 200 and one of the conductive layers 204. The solder mask 1000 is on the conductive layer 204, with the non-conductive sticker 1004 on the solder mask 1000 and the conductive sticker 1006 on the non-conductive sticker 1000. The additional non-conductive sticker 1008 is not included in this example. The laser drill 104 cuts the hole 106 through all these layers 200, 204, solder mask 1000, and stickers 1004, 1006. As shown in FIG. 15, the electroplating bath forms the metal layer 800 along the exposed surfaces inside the hole 106. Once this plating is completed (shown in FIG. 13), the entire stack of the non-conductive sticker 1004 and the conductive sticker 1006 are removed or peeled away, leaving a completed circuit board 1100 with a silkscreen 1300 and solder pads 1302 exposed and shown in FIG. 16.

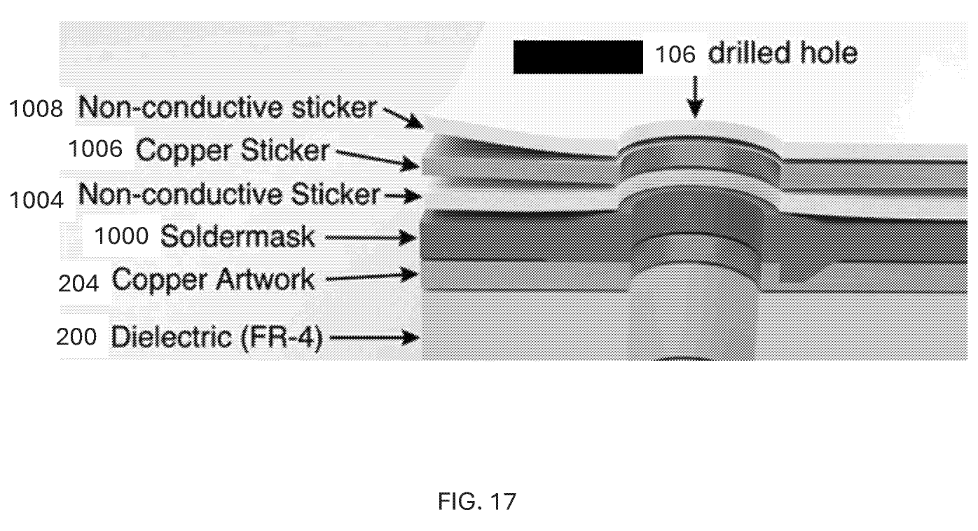

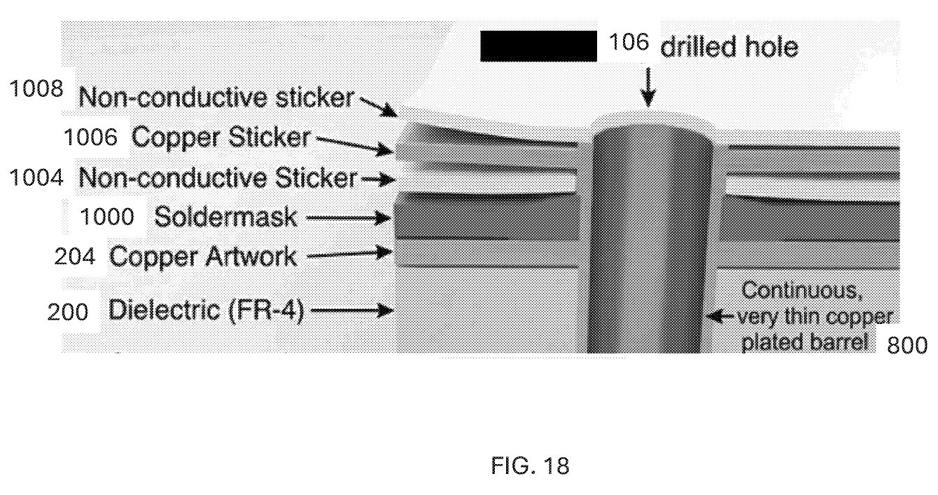

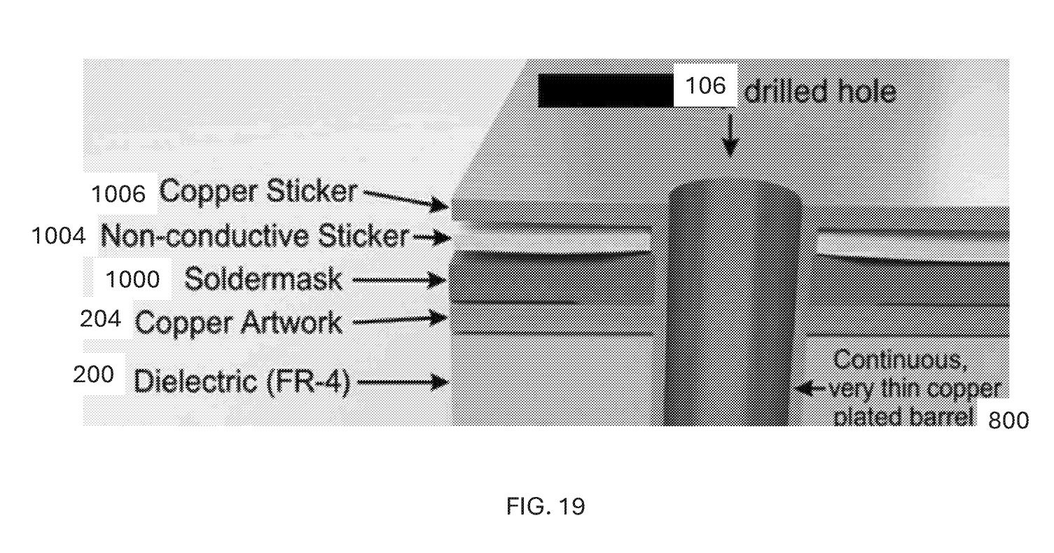

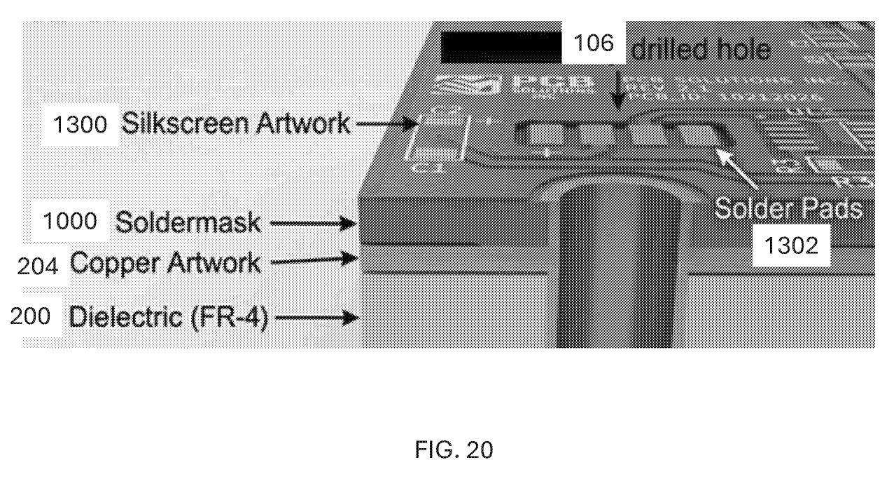

FIGS. 17 through 20 illustrate cross-sectional views of the PCB 102 at different stages of another method of plating a completed circuit board or device 1100. In FIG. 17, the PCB 102 is shown as including the dielectric layer 200 and one of the conductive layers 204. The solder mask 1000 is on the conductive layer 204, with the non-conductive sticker 1004 on the solder mask 1000 and the conductive sticker 1006 on the non-conductive sticker 1000. The additional non-conductive sticker 1008 is on the conductive sticker 1006. The laser drill 104 cuts the hole 106 through all these layers 200, 204, solder mask 1000, and stickers 1004, 1006, 1008. As shown in FIG. 18, the electroplating bath forms the metal layer 800 along the exposed surfaces inside the hole 106. After plating the metal layer 800 inside the hole 106, the top non-conductive sticker 1008 is removed, leaving the conductive (e.g., copper) sticker 1006 exposed, as shown in FIG. 19. This non-conductive sticker 1008 can be removed while the PCB 102 is in the electroplating bath, or the PCB 102 may be removed from the bath, the non-conductive sticker 1008 is removed, and then the PCB 102 is placed back into the bath. With the non-conductive sticker removed 1008, the entire conductive sticker 1006 is exposed to plating and is plated with conductive material from the bath. Once plating is completed, the conductive sticker 1006 and the non-conductive sticker 1004 are removed as shown in FIG. 20, leaving the completed circuit board 1100 with a silkscreen 1300 and solder pads 1302 exposed and shown in FIG. 20.

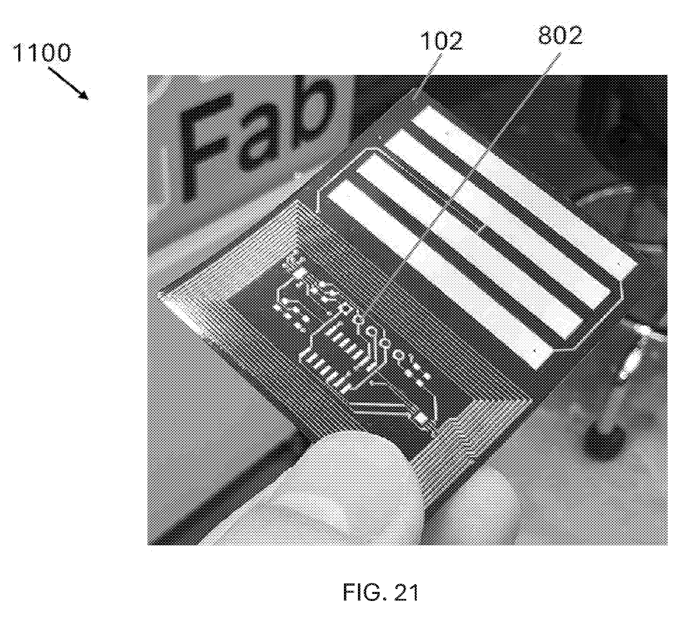

The finished device or circuit board 1100 shown in FIG. 21 represents the culmination of the process for forming conductive vias 802 in the PCB substrate 102. This device 1100 is the final product that incorporates the conductive vias 802, which plays a critical role in establishing electrical connections between different layers of the PCB. The finished device 1100 is a testament to the effectiveness of the novel method described, which significantly reduces the time and complexity traditionally associated with via formation. By eliminating the need for extensive chemical cleaning and preparation steps, the process not only enhances efficiency but also minimizes the use of hazardous chemicals, making the process more environmentally friendly. The finished device 1100 showcases the integration of complex electronic circuits, facilitated by the reliable and consistent conductive vias 802, which ensure optimal electrical performance and functionality.

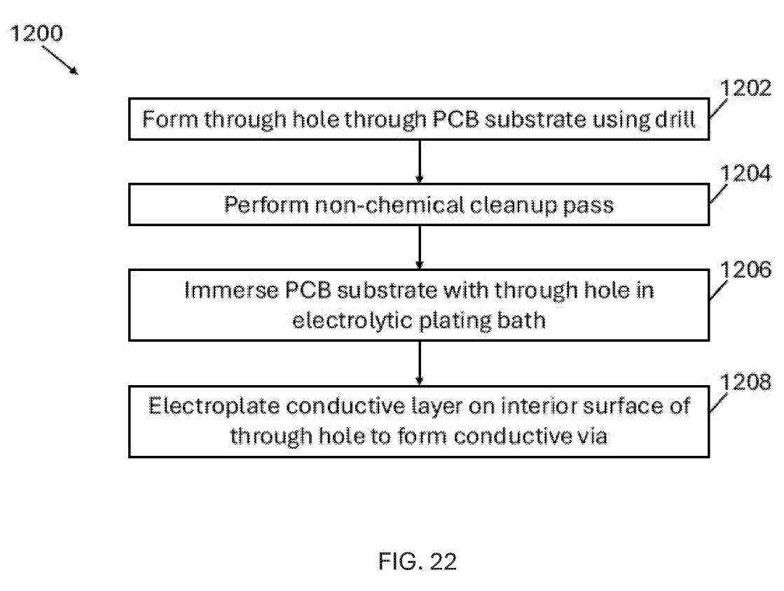

FIG. 22 illustrates a flow chart of one example of a method 1200 for forming conductive vias in a PCB substrate. The method 1200 can be used to create the conductive vias 802 described herein. At 1202, through holes are formed in the PCB substrate using a drill. This step can be executed using either a mechanical drill or a laser drill, each offering distinct advantages depending on the specific requirements of the PCB fabrication process. The mechanical drill is typically used for larger through holes, providing robust and precise cutting through the PCB substrate. On the other hand, a laser drill offers high precision and is particularly effective for creating smaller vias in high-density interconnect designs. The laser drill can be configured to operate with specific parameters, such as a pulsed laser with a pulse width of approximately 14 nanoseconds and a wavelength of 355 nm as one example, to optimize the drilling process and reduce damage to the substrate. Other pulse widths and/or wavelengths may be used, such as 200 picoseconds and 355 nm, 140 nanoseconds and 1064 nm. The drilling process generates a heat-affected zone along the interior surfaces of the holes, which becomes partially carbonized to serve as nucleation sites for electroplating.

At 1204, a non-chemical cleanup pass is optionally performed. In another example, the method 1200 does not include 1204. This operation can remove resin or glass melt that may have accumulated on the interior surfaces of the through holes during the drilling process. The non-chemical cleanup pass can be performed at a speed of at least 500 millimeters per second along the length of the through hole, ensuring that the interior surfaces are adequately prepared for the subsequent electroplating process. Alternatively, another speed may be used, such as 100 to 200 millimeters per second. This eliminates the need for traditional chemical cleaning and preparation steps, which are typically required to ensure the interior surfaces of the vias are adequately prepared for metallization.

At 1206, the PCB substrate with the through hole is immersed in an electrolytic plating bath. The plating bath contains a metal ion-containing plating solution, typically comprising copper ions, which facilitates the electroplating of the interior surfaces of the through hole. The solution may include additives such as surfactants to enhance plating efficiency. The immersion of the PCB substrate in the plating bath allows for the deposition of metal ions onto the nucleation sites provided by the heat-affected zone, thereby forming a conductive layer on the interior surfaces of the through hole.

At 1208, a conductive layer is electroplated on the interior surface of the through hole to form a conductive via. This step is facilitated by an electroplating device that is electrically connected to the PCB substrate, allowing the application of an electrical current for the deposition of metal ions from the plating solution onto the nucleation sites. The conductive layer formed during this step plays a significant role in establishing electrical connectivity between different layers of the PCB, enhancing the overall performance and reliability of the final electronic device.

As described herein, a method for forming a conductive via in a printed circuit board substrate can include obtaining a printed circuit board substrate comprising a dielectric material between at least a first conductive layer and a second conductive layer, and directing a pulsed laser through the printed circuit board substrate to form a through hole extending between the first conductive layer and the second conductive layer. The pulsed laser forms, along a side wall of the through hole, a partially conductive region comprising carbonized dielectric material and metal dust deposited from at least one of the first conductive layer or the second conductive layer. The method also can include electrically coupling at least one of the first conductive layer or the second conductive layer to a cathode, immersing the printed circuit board substrate in an electroplating bath, and electroplating conductive material onto the side wall of the through hole through electrical conduction provided by the partially conductive region to form the conductive via.

The dielectric material can include or can be FR-4. The partially conductive region can continuously extend through a thickness of the printed circuit board substrate along the side wall of the through hole. The partially conductive region can provide an electrically connected path between opposite surfaces of the printed circuit board substrate before completion of bulk electroplating.

The pulsed laser can have a wavelength of 355 nm and/or a pulse width of 14 nanoseconds. Directing the pulsed laser can include moving a laser beam along a bidirectional crosshatch pattern. The method also can include performing a cleanup pass on the side wall of the through hole after directing the pulsed laser and before immersing the printed circuit board substrate in the electroplating bath. Performing this cleanup pass can include moving the pulsed laser along a length of the through hole at a speed of at least 500 millimeters per second to remove resin or glass melt from the side wall of the through hole.

The method also can include immersing the printed circuit board substrate in an ion sequestration bath after electroplating the conductive via. The ion sequestration bath can include a sodium carbonate solution configured to convert soluble copper ions remaining on the printed circuit board substrate into an insoluble copper compound.

Also as described herein, a method for forming a conductive via in a printed circuit board substrate can include forming a circuit pattern in at least a first conductive layer and a second conductive layer on opposite surfaces of a printed circuit board substrate, providing at least a first non-conductive layer on the first conductive layer and providing at least a second non-conductive layer on the second conductive layer, providing at least a first outer conductive layer on the first non-conductive layer and providing at least a second outer conductive layer on the second non-conductive layer, directing a laser through the first outer conductive layer, the first non-conductive layer, the printed circuit board substrate, the second non-conductive layer, and the second outer conductive layer to form a through hole having a side wall including a partially conductive region, electrically coupling at least one of the first outer conductive layer or the second outer conductive layer to a cathode, immersing the printed circuit board substrate in a plating bath, and electroplating conductive material onto the side wall of the through hole through the partially conductive region while the first non-conductive layer and the second non-conductive layer inhibit electroplating on the circuit pattern to form the conductive via.

Each or at least one of first outer conductive layer and/or the second outer conductive layer can include copper tape. At least one of the first non-conductive layer and/or the second non-conductive layer can include Kapton tape. This Kapton tape can have a thickness of 1 mil. At least one of the first outer conductive layer and/or the second outer conductive layer can have a thickness of 1 mil.

The method can include removing the first outer conductive layer and the second outer conductive layer after electroplating the conductive via.

Also as described herein, a method for selectively electroplating a through hole in a printed circuit board substrate can include providing a printed circuit board substrate comprising a dielectric material between at least a first conductive layer and a second conductive layer, providing at least a first non-conductive adhesive sheet on the first conductive layer and providing at least a second non-conductive adhesive sheet on the second conductive layer, directing a laser through the first non-conductive adhesive sheet, the printed circuit board substrate, and the second non-conductive adhesive sheet to form a through hole having a side wall including a partially conductive region, electrically coupling at least one of the first conductive layer or the second conductive layer to a cathode, immersing the printed circuit board substrate in an electroplating bath while the first non-conductive adhesive sheet and the second non-conductive adhesive sheet cover surface regions adjacent the through hole, and electroplating conductive material onto the side wall of the through hole through the partially conductive region to form the conductive via.

The method also can include removing at least one of the first non-conductive adhesive sheet and/or the second non-conductive adhesive sheet after an initial portion of the electroplating and returning the printed circuit board substrate to the electroplating bath. Continued electroplating after removing the at least one of the first non-conductive adhesive sheet and/or the second non-conductive adhesive sheet deposits the conductive material onto at least one of the first conductive layer and/or the second conductive layer adjacent the through hole. The first non-conductive adhesive sheet and the second non-conductive adhesive sheet can reduce an area available for electroplating to increase current density at the through hole during an initial portion of the electroplating. The first non-conductive adhesive sheet and the second non-conductive adhesive sheet can expose the through hole to the electroplating bath while covering surrounding surface regions of the printed circuit board substrate during an initial portion of the electroplating.

Use of phrases such as “one or more of … and,” “one or more of … or,” “at least one of …and,” and “at least one of … or” are meant to encompass including only a single one of the items used in connection with the phrase, at least one of each one of the items used in connection with the phrase, or multiple ones of any or each of the items used in connection with the phrase. For example, “one or more of A, B, and C,” “one or more of A, B, or C,” “at least one of A, B, and C,” and “at least one of A, B, or C” each can mean (1) at least one A, (2) at least one B, (3) at least one C, (4) at least one A and at least one B, (5) at least one A, at least one B, and at least one C, (6) at least one B and at least one C, or (7) at least one A and at least one C.

As used herein, an element or step recited in the singular and proceeded with the word “a” or “an” do not exclude the plural of said elements or operations, unless such exclusion is explicitly stated. Furthermore, references to “one embodiment” of the invention do not exclude the existence of additional embodiments that incorporate the recited features. Moreover, unless explicitly stated to the contrary, embodiments “comprising,” “comprises,” “including,” “includes,” “having,” or “has” an element or a plurality of elements having a particular property may include additional such elements not having that property. In the appended claims, the terms “including” and “in which” are used as the plain-English equivalents of the respective terms “comprising” and “wherein.” Moreover, in the following clauses, the terms “first,” “second,” and “third,” etc. are used merely as labels, and do not impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function devoid of further structure.

The above description is illustrative, and not restrictive. For example, the above-described embodiments (and/or aspects thereof) may be used in combination with each other. In addition, many modifications may be made to adapt a particular situation or material to the teachings of the subject matter without departing from its scope. While the dimensions and types of materials described herein define the parameters of the subject matter, they are exemplary embodiments. Other embodiments will be apparent to one of ordinary skill in the art upon reviewing the above description. The scope of the subject matter should, therefore, be determined with reference to the appended claims, along with the full scope of equivalents to which such clauses are entitled.

This written description uses examples to disclose several embodiments of the subject matter, including the best mode, and to enable one of ordinary skill in the art to

practice the embodiments of subject matter, including making and using any devices or systems and performing any incorporated methods. The patentable scope of the subject matter is defined by the claims, and may include other examples that occur to one of ordinary skill in the art. Such other examples are intended to be within the scope of the claims if they have structural elements that do not differ from the literal language of the claims, or if they include equivalent structural elements with insubstantial differences from the literal languages of the claims.

What is claimed is:

1. A method for forming a conductive via in a printed circuit board substrate, the method comprising:
obtaining a printed circuit board substrate comprising a dielectric material between at least a first conductive layer and a second conductive layer;
directing a pulsed laser through the printed circuit board substrate to form a through hole extending between the first conductive layer and the second conductive layer, the pulsed laser forming, along a side wall of the through hole, a partially conductive region comprising carbonized dielectric material and metal dust deposited from at least one of the first conductive layer or the second conductive layer;
electrically coupling at least one of the first conductive layer or the second conductive layer to a cathode;
immersing the printed circuit board substrate in an electroplating bath; and
electroplating conductive material onto the side wall of the through hole through electrical conduction provided by the partially conductive region to form the conductive via.

2. The method of claim 1, wherein the dielectric material comprises FR-4.

3. The method of claim 1, wherein the partially conductive region extends continuously through a thickness of the printed circuit board substrate along the side wall of the through hole.

4. The method of claim 3, wherein the partially conductive region provides an electrically connected path between opposite surfaces of the printed circuit board substrate before completion of bulk electroplating.

5. The method of claim 1, wherein the pulsed laser has a wavelength of 355 nm.

6. The method of claim 1, wherein the pulsed laser has a pulse width of 14 nanoseconds.

7. The method of claim 1, wherein directing the pulsed laser comprises moving a laser beam along a bidirectional cross-hatch pattern.

8. The method of claim 1, further comprising:
performing a cleanup pass on the side wall of the through hole after directing the pulsed laser and before immersing the printed circuit board substrate in the electroplating bath, wherein performing the cleanup pass comprises moving the pulsed laser along a length of the through hole at a speed of at least 500 millimeters per second to remove resin or glass melt from the side wall of the through hole.

9. The method of claim 1, further comprising:
immersing the printed circuit board substrate in an ion sequestration bath after electroplating the conductive via, wherein the ion sequestration bath comprises a sodium carbonate solution configured to convert soluble copper ions remaining on the printed circuit board substrate into an insoluble copper compound.

10. A method for forming a conductive via in a printed circuit board substrate, the method comprising:
forming a circuit pattern in at least a first conductive layer and a second conductive layer on opposite surfaces of a printed circuit board substrate;
providing at least a first non-conductive layer on the first conductive layer and providing at least a second non-conductive layer on the second conductive layer;
providing at least a first outer conductive layer on the first non-conductive layer and providing at least a second outer conductive layer on the second non-conductive layer;
directing a laser through the first outer conductive layer, the first non-conductive layer, the printed circuit board substrate, the second non-conductive layer, and the second outer conductive layer to form a through hole having a side wall including a partially conductive region;
electrically coupling at least one of the first outer conductive layer or the second outer conductive layer to a cathode;
immersing the printed circuit board substrate in a plating bath; and
electroplating conductive material onto the side wall of the through hole through the partially conductive region while the first non-conductive layer and the second non-conductive layer inhibit electroplating on the circuit pattern to form the conductive via.

11. The method of claim 10, wherein the first outer conductive layer and the second outer conductive layer each comprise copper tape.

12. The method of claim 10, wherein at least one of the first non-conductive layer or the second non-conductive layer comprises Kapton tape.

13. The method of claim 12, wherein the Kapton tape has a thickness of 1 mil.

14. The method of claim 11, wherein at least one of the first outer conductive layer or the second outer conductive layer has a thickness of 1 mil.

15. The method of claim 10, further comprising:
removing the first outer conductive layer and the second outer conductive layer after electroplating the conductive via.

16. A method for selectively electroplating a through hole in a printed circuit board substrate, the method comprising:
providing a printed circuit board substrate comprising a dielectric material between at least a first conductive layer and a second conductive layer;
providing at least a first non-conductive adhesive sheet on the first conductive layer and providing at least a second non-conductive adhesive sheet on the second conductive layer;
directing a laser through the first non-conductive adhesive sheet, the printed circuit board substrate, and the second non-conductive adhesive sheet to form a through hole having a side wall including a partially conductive region;
electrically coupling at least one of the first conductive layer or the second conductive layer to a cathode;
immersing the printed circuit board substrate in an electroplating bath while the first non-conductive adhesive sheet and the second non-conductive adhesive sheet cover surface regions adjacent the through hole; and
electroplating conductive material onto the side wall of the through hole through the partially conductive region to form the conductive via.

17. The method of claim 16, further comprising:
removing at least one of the first non-conductive adhesive sheet or the second non-conductive adhesive sheet after an initial portion of the electroplating and returning the printed circuit board substrate to the electroplating bath.

18. The method of claim 17, wherein continued electroplating after removing the at least one of the first non-conductive adhesive sheet or the second non-conductive adhesive sheet deposits the conductive material onto at least one of the first conductive layer or the second conductive layer adjacent the through hole.

19. The method of claim 16, wherein the first non-conductive adhesive sheet and the second non-conductive adhesive sheet reduce an area available for electroplating to increase current density at the through hole during an initial portion of the electroplating.

20. The method of claim 16, wherein the first non-conductive adhesive sheet and the second non-conductive adhesive sheet expose the through hole to the electroplating bath while covering surrounding surface regions of the printed circuit board substrate during an initial portion of the electroplating.
